(19) United States
(12) Patent Application Publication
(10) Pub. No.: US 2014/0138345 A1
(43) Pub. Date: May 22, 2014

(54) METHODS OF FORMING CONDUCTIVE PATTERNS USING INKJET PRINTING METHODS

(71) Applicant: Samsung Electronics Co., Ltd., Suwon-Si (KR)

(72) Inventors: Jin-seok HONG, Seoul (KR); Young-ki HONG, Anyang-si (KR); Joong-hyuk KIM, Seoul (KR); Sung-gyu KANG, Suwon-si (KR); Seung-ho LEE, Suwon-si (KR)

(21) Appl. No.: 13/904,167

(22) Filed: May 29, 2013

(30) Foreign Application Priority Data
Nov. 21, 2012 (KR) 10-2012-0132604

(51) Int. Cl. H05K 3/40

(52) U.S. Cl. CPC H05K 3/40
USPC 216/18; 427/98.4

(57) ABSTRACT

A method of forming a conductive pattern includes forming a first partition and a second partition which are spaced apart from each other on a substrate, the first and second partitions defining a trench. The method includes discharging ink into the trench to form ink droplets pinned in a boundary region of the first and second partitions. The method further includes the boundary region including a region between a top side and an outer side of the first and second partitions, the ink including conductive particles. The method includes performing drying and sintering processes to form the conductive pattern in the trench, the conductive pattern including the conductive particles.

### CROSS-REFERENCE TO RELATED APPLICATION

This application claims the benefit of Korean Patent Application No. 10-2012-0132604, filed on Nov. 21, 2012, in the Korean Intellectual Property Office, the disclosure of which is incorporated herein in its entirety by reference.

### BACKGROUND

1. Field

At least one example embodiment relates to methods for forming conductive patterns on a substrate using an inkjet printing method.

2. Description of the Related Art

In general, an inkjet printing apparatus is an apparatus for printing a predetermined image by discharging micro-droplets of ink to a desired location on a printing medium through the nozzle of an inkjet head. Recently, such an inkjet printing apparatus has been applied to fields involving flat panel displays such as LCDs (Liquid Crystal Displays) and OLEDs (Organic Light Emitting Devices), flexible displays such as e-paper, printed electronics such as metal wiring, OTFTs (Organic Thin Film Transistors), and biotechnology or bioscience, in addition to image printing.

One of the important technical issues in applying a process of forming conductive patterns to the above-described fields by an inkjet printing apparatus is to form a thick wiring with a fine width without disconnection or short circuit. Recently, as electronic equipment has rapidly been subjected to miniaturization, high performance, and multi-functionalization, wiring substrates for mounting electronic devices such as semiconductor devices also require high densification and high reliability. For instance, TFT-LCDs require ultra-high resolution or large screens, or circuits of semiconductor devices are highly densified, thick wirings with a fine line width are required in clearing wiring resistance increase and RC delay (Resistance×Capacitance Delay).

### SUMMARY

At least one example embodiment provides a method(s) of manufacturing thick conductive patterns by filling ink in a target area on a substrate by an inkjet printing process.

According to at least one example embodiment, a method of forming a conductive pattern may include forming a first partition and a second partition which are spaced apart from each other on a substrate, the first and second partitions defining a trench. The method may include discharging ink into the trench to form ink droplets pinned in a boundary region of the first and second partitions, the boundary region including a region between a top side and an outer side of the first and second partitions, the ink including conductive particles. The method may include performing drying and sintering processes to form the conductive pattern in the trench, the conductive pattern including the conductive particles.

According to at least one example embodiment, the method further includes forming first and second separation grooves adjacent to the first and second partitions.

According to at least one example embodiment, the first and second partitions have widths Pw and the first and second separation grooves have widths Pd, and Pw/Pd ranges from about 0.7 to about 1.3.

According to at least one example embodiment, the first and second partitions include a plurality of partitions and the first and second separation grooves include a plurality of separation grooves, the plurality of partitions are separated by the plurality of first and second separation grooves, and pinning of the ink droplets occurs in a boundary between the top side and the outer side of the partition that is located at a outermost side.

According to at least one example embodiment, the method further includes forming an ink phobic material layer on at least the top and outer sides of the first and second partitions before the discharging the ink.

According to at least one example embodiment, the forming the first and second partitions and the forming the first and second separation grooves includes etching the substrate.

According to at least one example embodiment, the forming the first and second partitions and the forming the first and second separation grooves includes forming a photosensitive resin layer on the substrate and etching the photosensitive resin layer.

According to at least one example embodiment, a method for forming a conductive pattern includes forming a first and second partition on a substrate. The first and second partitions may include inner sides which are spaced apart from each other to define a trench in the substrate, a top side extending in a lateral direction from top edges of the inner sides of the partition, and outer sides extending in a downward direction from outer end portions of the top side. The method may further include discharging ink into the trench to form ink droplets pinned in a boundary region. The boundary region may include a region between the top sides and the outer sides, the ink including conductive particles. The method may further include performing drying and sintering processes to form the conductive pattern in the trench. The conductive pattern may include the conductive particles.

According to at least one example embodiment, the method further includes forming separation grooves adjacent to the first and second partitions, the separation grooves having a concave shape.

According to at least one example embodiment, the first and second partitions have widths Pw and the separation grooves have widths Pd, and Pw/Pd ranges from about 0.7 to about 1.3.

According to at least one example embodiment, the method further includes forming an ink phobic material layer on at least the top and outer sides of the first and second partitions before the discharging the ink.

According to at least one example embodiment, the forming the first and second partitions and the forming the separation grooves includes etching the substrate.

According to at least one example embodiment, the forming the first and second partitions and the forming the separation grooves includes forming a photosensitive resin layer on the substrate and etching the photosensitive resin layer.

According to at least one example embodiment, a method of forming a conductive pattern may include forming at least one trench in a substrate. The method may include forming at least first and second grooves on opposite sides of the at least one trench, the at least first and second grooves extending in a substantially same direction as the at least one trench. The method may include discharging ink into the at least one trench, the ink including conductive particles. The method may include evaporating the ink to form the conductive pattern in the at least one trench.

According to at least one example embodiment, the discharging the ink includes discharging the ink into the at least one trench and on a region of the substrate between the first and second grooves.

According to at least one example embodiment, the discharging the ink includes discharging at least one ink droplet having an obtuse contact angle with respect to a top surface the region of the substrate between the first and second grooves.

According to at least one example embodiment, the forming the at least first and second grooves includes forming the at least first and second grooves to have a depth different from the at least one trench.

According to at least one example embodiment, the forming the at least first and second grooves includes forming third and fourth grooves, the third and fourth grooves being formed on opposite sides of the at least one trench and at a distance further from the at least one trench than the first and second grooves.

According to at least one example embodiment, the discharging the ink includes discharging the ink such that the ink covers the first and second grooves and a region of the substrate between the third and fourth grooves.

According to at least one example embodiment, the discharging the ink includes discharging at least one ink droplet having an obtuse contact angle with respect to a top surface the region of the substrate between the third and fourth grooves.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic diagram illustrating an example of an inkjet printing apparatus applied to a process of forming a conductive pattern according to at least one example embodiment;

FIG. 2A is a view illustrating a trench defined by first and second partitions, and first and second separation grooves formed in a substrate according to at least one example embodiment;

FIGS. 2B and 2C are views showing an example of a process of defining a trench according to at least one example embodiment;

FIG. 3A is a view illustrating an ink droplet formed by discharging ink to the trench according to at least one example embodiment;

FIG. 3B is a view illustrating an ink droplet formed by the ink discharged to the trench when there are not first and second partitions;

FIG. 3C is a view illustrating a state that a contact angle is pinned in the boundary between the top side and the outer side of the partition according to at least one example embodiment;

FIG. 3D is a view illustrating a state that conductive particles remaining in the trench after drying according to at least one example embodiment;

FIG. 4A is a view illustrating a contact angle of liquid on a solid surface;

FIG. 4B is a view illustrating a state of liquid on a solid surface when there is a big difference in surface energy;

FIG. 4C is a view illustrating a state of liquid on a solid surface when there is a small difference in surface energy;

FIG. 5 is a graph illustrating a result in which a relationship between a ratio of width of a partition to width of a separation groove and maximum width of an ink droplet on a substrate is simulated according to at least one example embodiment;

FIG. 6 is a view illustrating an example of a substrate on which an ink phobic material layer is formed according to at least one example embodiment;

FIGS. 7A to 7C are views illustrating other examples of a trench structure which enables pinning of a contact angle according to at least one example embodiment; and

FIGS. 8A and 8B are views illustrating an example of a process of forming a photosensitive resin layer on a substrate and etching the photosensitive resin layer to define a trench according to at least one example embodiment.

### DETAILED DESCRIPTION OF EXAMPLE EMBODIMENTS

Example embodiments will be understood more readily by reference to the following detailed description and the accompanying drawings. The example embodiments may, however, be embodied in many different forms and should not be construed as being limited to those set forth herein. Rather, these example embodiments are provided so that this disclosure will be thorough and complete. In at least some example embodiments, well-known device structures and well-known technologies will not be specifically described in order to avoid ambiguous interpretation.

It will be understood that when an element is referred to as being “connected to” or “coupled to” another element, it can be directly on, connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the example embodiments.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises,” “comprising,” “includes,” and/or “including” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which these example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “below”, “beneath”, “lower”, “above”, “upper”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

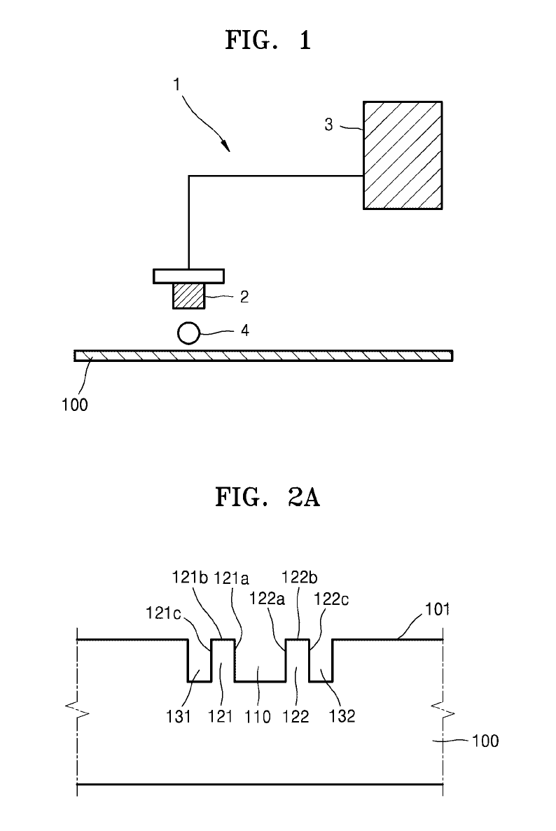

FIG. 1 is a schematic diagram illustrating an example of an inkjet printing apparatus applied to a process of forming a conductive pattern according to at least one example embodiment. Referring to FIG. 1, an inkjet printing apparatus 1 includes an inkjet head 2. The inkjet head 2 may be a liquid discharge device that discharges ink according various methods, such as a piezoelectric method using piezoelectric driving force, an electrostatic method using electrostatic driving force, or a piezoelectric/electrostatic combined method. The inkjet head 2 may be movably installed at the upper part of a substrate 100 and may discharge ink 4 onto the surface of the substrate 100 to form desired (or alternatively, predetermined) printing patterns. The inkjet head 2 is connected to an ink chamber 3 for supplying the ink 4.

The ink 4 may be a solution in which conductive particles such as Au, Ag or Cu particles are dispersed into a solvent. The conductive particles may remain on the substrate 100 when the solvent is evaporated through a drying process after discharging the ink 4 onto the substrate 100. Thereafter, a sintering process is performed to form a conductive pattern, i.e., a wiring on the substrate 100.

As described above, the ink 4 may include conductive particles that are dispersed into the solvent which evaporates through the drying process. Since a ratio of the conductive particles in the ink 4 is very low, a thickness of the conductive particles remaining on the substrate 100 after passing through the drying process is about one out of several to tens thinner than the amount of ink 4 applied to the substrate 100. Moreover, a thickness of the conductive pattern may be further decreased by performing a densification process through high temperature sintering. Although a method of increasing the amount of the ink 4 to increase thickness of the conductive pattern is taken into account, there is a risk of short circuit because the ink may spread to adjacent conductive patterns. Although a method of forming a trench with a large aspect ratio, i.e., a deep trench on the substrate, is considered as another method, the aspect ratio of the trench is limited due to processing factors.

Hereinafter, a method for forming a conductive pattern that is capable of forming highly reliable, thick wiring relatively easily is described.

[Formation of Trench 110]

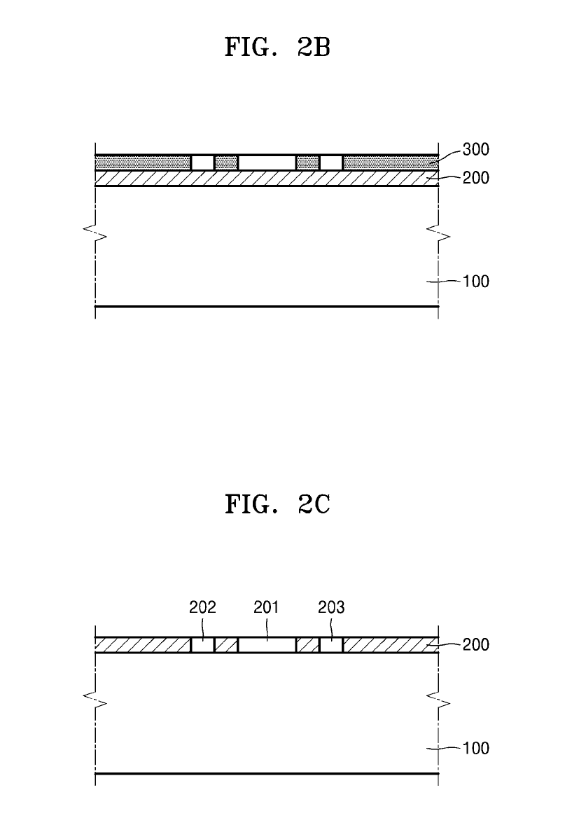

FIG. 2A is a view illustrating a trench defined by first and second partitions, and first and second separation grooves formed in a substrate according to at least one example embodiment. FIGS. 2B and 2C are views showing an example of a process of defining a trench according to at least one example embodiment.

Referring to FIG. 2A, a trench 110 on which a conductive pattern is to be formed is defined in a substrate 100. Examples of the substrate 100 may include a silicon (Si) substrate, a glass substrate, a quartz substrate, etc. The trench 110 is defined by first and second partitions 121 and 122 which are spaced apart from each other. The trench 110 is defined by respective inner sides 121a and 122a of the first and second partitions 121 and 122. The first and second partitions 121 and 122 include top sides 121b and 122b extending to the outer sides from top edges of the inner sides 121a and 122a. Outer sides 121c and 122c of the first and second partitions 121 and 122 extending a downward direction from the top sides 121b and 122b.

In the case of an enclosed trench, the first and second partitions 121 and 122 may be connected to each other. That is, the first and second partitions 121 and 122 form a partition having an inner side, a top side and an outer side. First and second separation grooves 131 and 132 are formed at the outer sides of the first and second partitions 121 and 122. The first and second separation grooves 131 and 132 separate the first and second partitions 121 and 122 and the top side 101 of the substrate 100, and form boundaries with partitions (which is not illustrated in drawings) for forming another adjacent trench (which is not illustrated in drawings).

Therefore, it should be understood that the first and second partitions 121 and 122 illustrated in FIG. 2A may be separate partitions which are spaced apart from each other when a trench 110 is an open trench, or first and second partitions 121 and may be partitions spaced apart from each other when the trench 110 is an enclosed trench.

The above described first and second partitions 121 and 122 and first and second separation grooves 131 and 132 are formed by etching the substrate 100. For instance, when a silicon substrate is employed as the substrate 100, a mask layer 200 is formed on the top side 101 of the substrate 100 as illustrated in FIG. 2B. For example, the mask layer 200 is a SiO₂ layer. The SiO₂ layer is formed by oxidizing the substrate 100. Next, a photoresist layer 300 is formed on the mask layer 200, and the photoresist layer 300 may be patterned by a method, such as a photolithography method, to expose a part of the mask layer 200. As illustrated in FIG. 2C, a mask layer 200 having openings 201, 202 and 203 formed therein is formed by patterning the mask layer 200 using the photoresist layer 300 as a mask and removing the photoresist layer 300. The openings 201, 202 and 203 respectively correspond to areas in which the trench 110 and the first and second separation grooves 131 and 132 are to be formed. For instance, the process of patterning the mask layer 200 may be performed by a wet etching process using an HF solution (buffered Hydrogen Fluoride acid) or a plasma dry etching process. Next, the substrate 100 is etched by using the mask layer 200 as an etching mask. Etching may be performed by a wet and/or dry etching process. For instance, an etchant may vary according to materials of the substrate 100. For instance, an etchant such as KOH (potassium hydroxide) may be used in the case of a single crystalline silicon substrate, and an acidic etchant in which nitric acid and hydrofluoric acid are mixed may be used in the case of a polycrystalline silicon substrate. When the substrate 100 is a glass or quartz substrate, a mask layer and an etchant formed from materials suitable to such a substrate are employed. As illustrated in FIG. 2A, the trench 110 is defined by the first and second partitions 121 and 122 which are spaced apart from each other. Further, the substrate 100, which has the first and second separation grooves 131 and 132 positioned at the outer sides of the first and second partitions 121 and 122, is manufactured by removing the mask layer 200 after conducting the etching process.

[Formation of Ink Droplets]

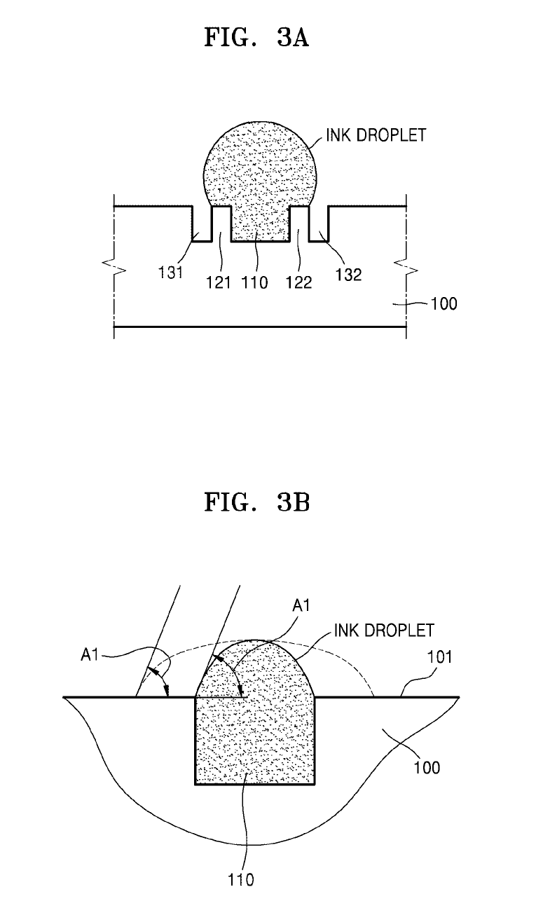

Subsequently, the process of discharging ink to the trench 110 using the inkjet printing apparatus 1 illustrated in FIG. 1 is carried out. The ink may be discharged to fill the trench 110. For example, the ink may be discharged into the trench 110 while moving the inkjet head 2 in the lengthwise direction of the trench 110. Then, the ink may be filled in the trench 110 as illustrated in FIG. 3A. Referring to FIG. 3A, after the ink is filled in the trench 110, the ink may form droplets that wet the top sides 121b and 122b of first and second partitions 121 and 122 due to surface tension.

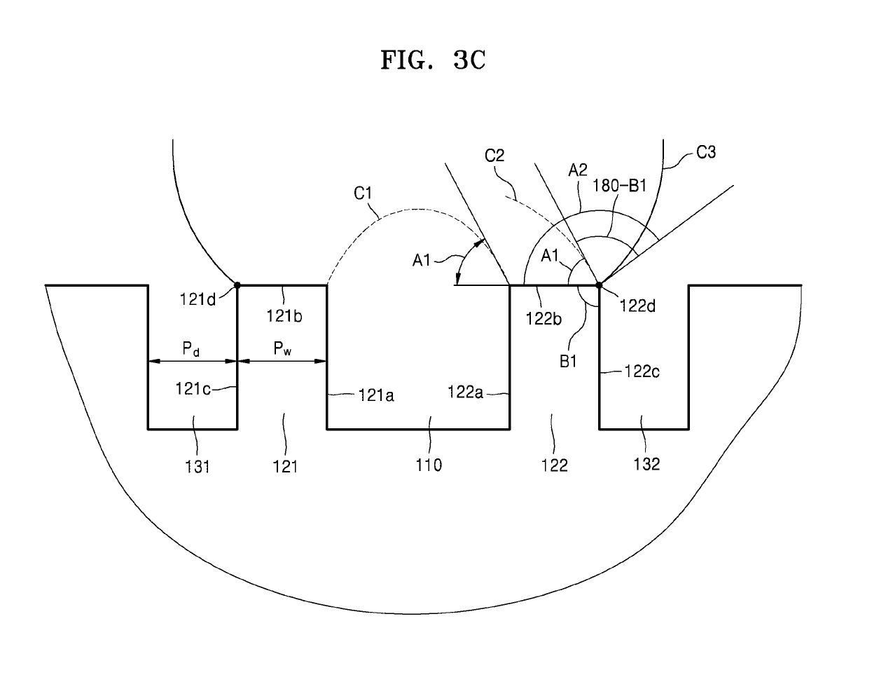

FIG. 4A shows a droplet (e.g., an ink droplet) that retains a lens shape when in contact with a horizontal plane of solid. The droplet has a curved surface, and an angle between the surface of the solid and a tangent line drawn from a contact point between the solid and droplet to the surface of the droplet is a contact angle θ. The contact angle θ is generally determined according to the type of liquid and solid at issue. For example, the larger the contact angle θ, the more phobic the liquid is against the solid. The smaller the contact angle θ, the more philic the liquid is with the solid. Further, as a surface energy difference between solid and liquid increases, the contact angle θ increases. If the contact angle θ is relatively large, then a liquid may take a droplet shape on the solid surface as illustrated in FIG. 4B. As shown in FIG. 4B, a gap may form between the adjacent droplets at a relatively large contact angle. If the contact angle θ is small, liquid spreads along the surface of the solid such that the adjacent droplets combine with each other, and the solid surface is wetted as illustrated in FIG. 4C.

The amount of ink that is discharged into the trench 110 may depend on a contact angle between the substrate 100 and the ink. In other words, the amount of ink discharged into the trench 110 may be controlled such that ink discharged on the top side 101 of the substrate 100 retains the shape of droplets, and does not spread along the top side 101. Otherwise, the ink may flow along the top side 101 of the substrate 100 and cause non-uniformed wiring if the ink exceeds the amount, and/or a short circuit if the ink spills into an adjacent trench (which is not illustrated in drawings). Referring to FIG. 3B, the discharged ink having a volume greater than that of the trench 110 is formed as a droplet which has a contact angle A1 with the top side 101 of the substrate 100 if there are not first and second partitions 121 and 122 or first and second separation grooves 131 and 132. Namely, the amount of ink discharge into the trench 110 is limited to the shape of a droplet illustrated in FIG. 3B so that the ink does not spread along the top side 101 of the substrate 100. As ink accumulates in the trench 110, the ink spreads along the top side 101 of the substrate 100 while maintaining the contact angle A1. As the contact angle increases, the size of the droplet increases. However, there is a limitation in increasing the contact angle since the contact angle is determined by a surface energy difference between the substrate 100 and the ink as described above.

According example embodiments of the general inventive concepts, an effect of increasing the contact angle may be obtained by forming first and second partitions 121 and 122 and first and second separation grooves 131 and 132, thereby inducing a pinning phenomenon in the boundary between the substrate 100 and ink droplets. Referring to FIG. 3C, the ink may be discharged into the trench 110 surrounded by inner sides 121a and 122a of the first and second partitions 121 and 122 to form an ink droplet having a contact angle A1 with top sides 121b and 122b of the first and second partitions 121 and 122. As the ink is continuously discharged, an ink droplet C1 spreads up to boundaries 121d and 122d while maintaining the contact angle A1 with the top sides 121b and 122b to form an ink droplet C2. Boundaries 121d and 122d are between the respective outer sides 121c and 122c and the respective top sides 121b and 122b adjacent to the first and second separation grooves 131 and 132. However, since pinning of the contact angle is generated at the boundaries 121d and 122d, the contact angle shifts from the top sides 121b and 122b to the outer sides 121c and 122c. Accordingly, the contact angle may change from A1 to A2 to form an ink droplet C3 having a contact angle A2 with the top sides 121b and 122b at the boundaries 121d and 122d. If an angle formed between the top side 121b or 122b and the outer side 121c or 122c is B1, a contact angle A2 after pinning becomes A1+(180°−B1) to obtain a contact angle increasing effect as much as 180°−B1. Accordingly, a relatively large amount of ink is discharged into the trench 110 without undesired spreading of ink by inducing pinning of the contact angle in the boundaries 121d and 122d between the top side 121b or 122b and the outer side 121c or 122c. That is, a relatively large amount of ink may be discharged into the trench 110 even without having to increase depth of the trench 110.

[Drying and Sintering]

According to at least one example embodiment, the ink may undergo an evaporating process(es) that includes drying and/or sintering the ink. For instance, the ink may be naturally dried by maintaining the ink at room temperature for about several hours. Alternatively or additionally, the ink may be maintained at a drying temperature higher than room temperature in order to dry the ink promptly. As the solvent is evaporates during the drying process, droplets of ink are naturally contracted, and conductive particles remain in the trench 110 as illustrated in FIG. 3D. The sintering process may be conducted after the drying process. For example, the sintering process may be performed at a temperature of about 500° C. to 700° C. for about one minute using an electric furnace. However, the above conditions for drying and sintering are just one example and example embodiments are not limited thereto. For example, the drying and sintering conditions may be appropriately selected by considering materials of the substrate 100 and the ink.

### Test Example 1

Ink: silver (Ag) nanoparticles, 7.5 particles vol %

Trench: 3.5 μm (depth)×3 μm (width)

Sintering condition: 500° C. to 700° C., within one minute

In a comparative example, a trench 110 having a structure as illustrated in FIG. 3B produced a conductive pattern having a thickness of about 1.54 μm in the trench 110 by sintering the printed ink droplets after printing ink droplets of 140 femto-liters (fl) twelve times with a gap of 20 μm. As illustrated in FIGS. 3A and 3C, a trench 110 according to an example embodiment produced a conductive pattern having a thickness of about 2.81 μm in the trench 110 by sintering the printed ink droplets after printing ink droplets of 130 fl six times with a gap of 4 to 6 μm. As is evident from above, according to at least one example embodiment of the general inventive concepts, pinning of the contact angle allows for uniform and thick conductive patterns to be obtained by discharging more ink to the trench 110 while mitigating (or, or alternatively minimizing) spreading of the ink.

### Test Example 2

Ink: silver (Ag) nanoparticles, 7.5 particles vol %

Trench: 3.5 μm (depth)×3 μm (width)

Sintering condition: 600° C. to 700° C., within one minute

In a comparative example, a trench 110 having a structure as illustrated in FIG. 3B produced a conductive pattern having a thickness of about 1.06 μm in the trench 110 by sintering the printed ink droplets after printing (220 fl/μm) ink droplets of 220 fl twenty times with a gap of 20 μm. As illustrated in FIGS. 3A and 3C, a trench 110 according to an example embodiment produced a conductive pattern having a thickness of about 1.12 μm in the trench 110 by sintering the printed ink droplets after printing (53 fl/μm) ink droplets of 160 fl eight times with a gap of 24 μm on the trench 110. As is evident from above, at least one example embodiment of the general inventive concepts uses pinning of the contact angle to achieve conductive patterns with a similar thickness as in the comparative example. However, a trench having a structure according to at least one example embodiment achieves these results using a smaller amount of ink because spreading of the ink is mitigated compared to the comparative example.

If widths Pd of the first and second separation grooves 131 and 132 are too small, ink may spread over the first and second separation grooves 131 and 132. This may deteriorate uniformity of the conductive patterns and cause a short circuit with adjacent other conductive patterns. If widths of the first and second partitions 121 and 122 are too small, an effect of increasing the amount of ink is reduced, and a possibility of spreading ink over the first and second separation grooves 131 and 132 is increased. Since an ink spreading area is enlarged if the widths of the first and second partitions 121 and 122 are too large, conductive particles may not enter the trench 110 in the drying process, but may remain on the top sides 121b and 122b of the first and second partitions 121 and 122 such that conductive patterns are formed in a non-uniformed shape.

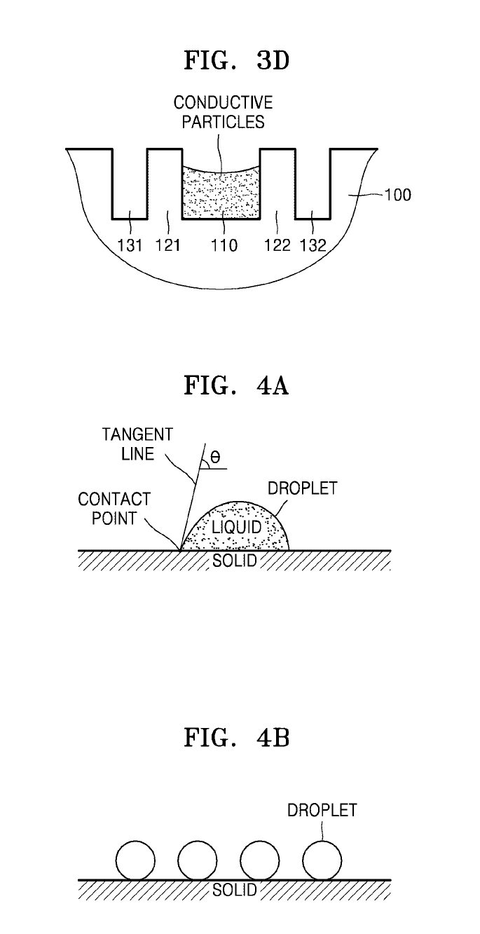

FIG. 5 is a graph illustrating a result in which a relationship between a ratio of width of a partition to width of a separation groove and maximum width of an ink droplet on a substrate is simulated according to at least one example embodiment.

FIG. 5 shows a graph illustrating a result in which a relationship between a ratio Pw/Pd of widths Pw of first and second partitions 121 and 122 to widths Pd of first and second separation grooves 131 and 132 and the maximum width of an ink droplet formed in the trench 110 is simulated.

FIG. 5 assumes the following conditions:

Contact angle between the substrate and ink: 53°

Surface tension of ink: 22 mN/m

Width and depth of the trench 110: 3 μm

Diameter of ink discharged: 8 μm

As shown in FIG. 5, the maximum width of the ink droplet rapidly increases if the ratio Pw/Pd is smaller than about 0.7. This means that the ink rapidly spreads over the first and second separation grooves 131 and 132 if the widths of the first and second partitions 121 and 122 are too small. The maximum width of the ink droplet also rapidly increases if the ratio Pw/Pd exceeds about 1.3. This means that the ink spreads widely along the top sides 121b and 122b of the first and second partitions 121 and 122. An increased maximum width of the ink droplet means that a thickness of a conductive pattern is decreased and a width of the conductive pattern is increased after drying and sintering. Therefore, a thick conductive pattern with a fine line width may be formed by selecting the ratio Pw/Pd ranging from about 0.7 to about 1.3. In other words, other structures having a height that is equivalent to those of the first and second partitions 121 and 122 do not exist within a distance corresponding to at least about 0.8 to about 1.4 times of the Pw at the outer sides of the first and second partitions 121 and 122.

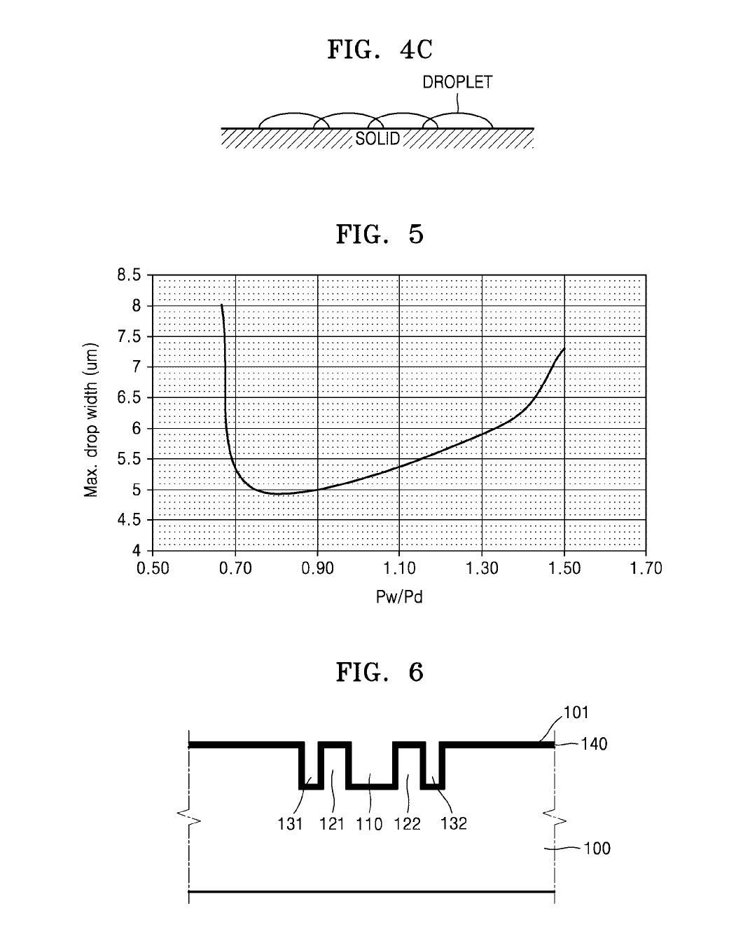

FIG. 6 is a view illustrating an example of a substrate on which an ink phobic material layer is formed according to at least one example embodiment.

As illustrated in FIG. 6, an ink phobic material layer 140 may be formed on at least the top sides 121b and 122b and the outer sides 121c and 122c of the first and second partitions 121 and 122 before conducting the step of discharging the ink in order to obtain a relatively large contact angle. The ink phobic material layer 140 is selected by taking into account the material of the substrate 100 and properties of the ink. The ink phobic material layer 140 may be a SAM (Self-Assembled Monolayer) or an organic film layer including a fluorine component. Self-assembling materials forming the SAM (Self-Assembled Monolayer) may be formed by compounds such as organic silicon compounds. For example, the organic silicon compounds may be compounds represented by RSiX₃, wherein X is halogen or an alkoxy group, and R is n-alkyl groups (n-CₙnH₂ₙ₊₁) including n-alkyl silanes such as n-alkyl trichlorosilane, n-alkyl trialkoxysilane, and others. The ink phobic material layer 140 may be formed by coating self-assembling materials or organic materials including a fluorine component by a process of deep coating, spin coating, or other coating process. For instance, after mixing self-assembling materials or organic materials including a fluorine component with a solvent to form a solution, the substrate 100 may be exposed to the solution. In order to easily form an ink phobic material layer 140, a process of removing foreign materials on the surface of the substrate 100 may be performed first. For instance, the process of removing the foreign materials may be conducted by irradiating deep UV (ultraviolet rays), UV-ozone, oxygen plasma and/or argon plasma onto the surface of the substrate 100.

Although examples of forming the first and second partitions 121 and 122 and the first and second separation grooves 131 and 132 by etching the substrate 100 are described above, example embodiments are not limited thereto. For instance, the first and second partitions 121 and 122 and the first and second separation grooves 131 and 132 may be formed by forming a photosensitive resin layer (e.g., a photoresist layer) on the substrate 100, and etching the photosensitive resin layer.

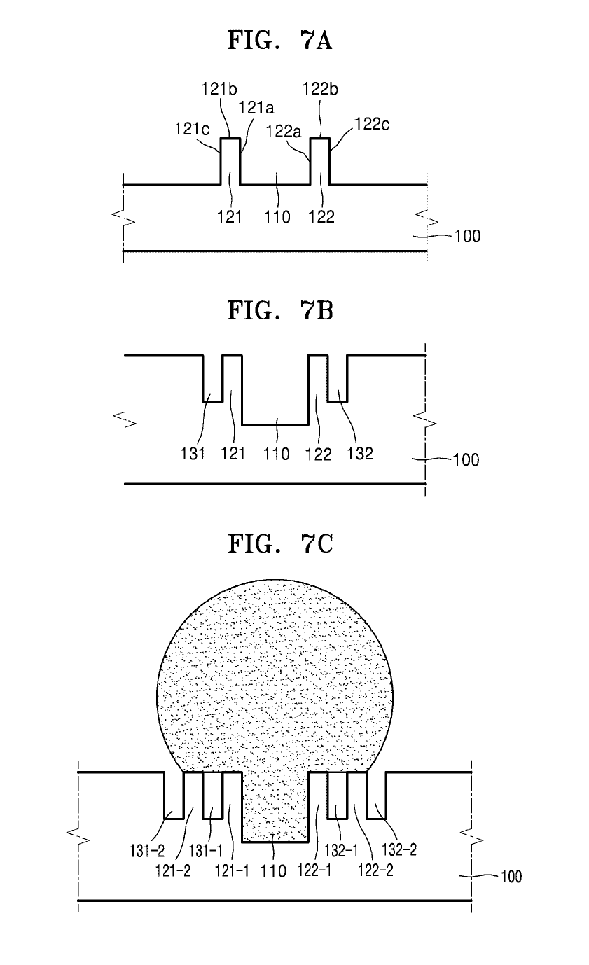

A structure of the trench 110 is not limited to the example illustrated in FIG. 2A. FIGS. 7A to 7C are views illustrating other examples of a trench structure which enables pinning of a contact angle according to at least one example embodiment.

For instance, as illustrated in FIG. 7A, it is possible to form a trench which is free of other structures having a height that is equal to those of the first and second partitions 121 and 122 within a distance corresponding to about 0.8 to about 1.4 times of the above-mentioned Pw at the outer sides of the first and second partitions 121 and 122. Namely, the first and second partitions 121 and 122 may be formed in such a shape that inner sides 121a and 122a, top sides 121b and 122b, and outer sides 121c and 122c are defined.

Further, as illustrated in FIG. 7B, a depth of the trench 110 may be deeper than those of the first and second separation grooves 131 and 132. Because this enables more ink to be discharged into the trench, a deep trench may be beneficial in the formation of a thick conductive pattern.

Further, as illustrated in FIG. 7C, a substrate 100 may include innermost partitions 121-1 and 121-2, outermost partitions 122-1 and 122-2, innermost separation grooves 131-1 and 131-2, and outermost separation grooves 132-1. In this case, the trench 110 may be defined by the innermost partitions 121-1 and 122-1. The innermost partition 121-1 and the outermost partition 121-2 may be separated by the innermost separation groove 131-1. Similarly, the innermost partition 122-1 and outermost partition 122-2 may be separated by the outermost separation groove 132-1. As shown in FIG. 7C, the ink does not fill the innermost separation grooves 131-1 and 132-1, and pinning of the contact angle occurs in the boundaries between the top side and the outer side of the outermost partitions 121-2 and 122-2. Therefore, more ink is discharged into the trench to increase a thickness of the conductive pattern. The condition of selecting a ratio Pw/Pd ranging from about 0.7 to about 1.3 may be applied to widths Pw of the outermost partitions 121-2 and 122-2 and widths Pd of the outermost separation grooves 131-2 and 132-2.

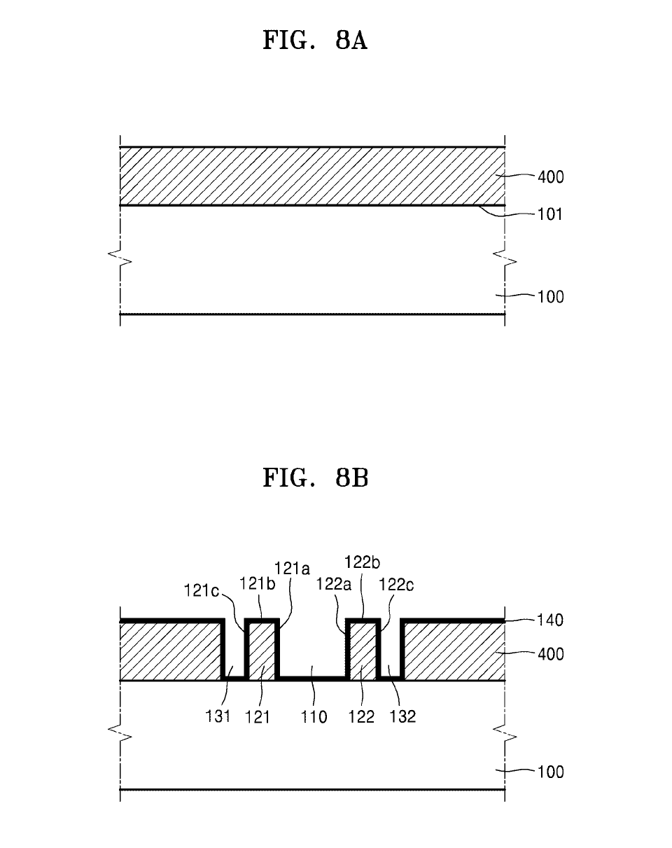

FIGS. 8A and 8B are views illustrating an example of a process of forming a photosensitive resin layer on a substrate and etching the photosensitive resin layer to define a trench according to at least one example embodiment

As illustrated in FIG. 8A, a photosensitive resin layer 400 may be formed on the top side 101 of the substrate 100. Examples of the photosensitive resin layer 400 may include negative and positive photoresist layers. The photosensitive resin layer 400 is patterned by methods such as a photolithography method to form the first and second partitions 121 and 122 defining the trench and the first and second separation grooves 131 and 132 formed at the outer sides of the first and second partitions 121 and 122 as illustrated in FIG. 8B. Further, an ink phobic material layer 140 may be formed on at least top sides 121b and 122b and outer sides 121c and 122c of the first and second partitions 121 and 122 in order to obtain a large contact angle. The photosensitive resin layer 400 may be removed before performing the sintering process after performing the drying process. For instance, oxygen plasma may be irradiated to remove the ink phobic material layer 140, and acetone is used to remove the photosensitive resin layer 400. The skilled in the related art will see that structures illustrated in FIGS. 7A to 7C may also be formed by the etching process of the photosensitive resin layer.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A method of forming a conductive pattern comprising:
forming a first partition and a second partition which are spaced apart from each other on a substrate, the first and second partitions defining a trench;
discharging ink into the trench to form ink droplets pinned in a boundary region of the first and second partitions, the boundary region including a region between a top side and an outer side of the first and second partitions, the ink including conductive particles; and
performing drying and sintering processes to form the conductive pattern in the trench, the conductive pattern including the conductive particles.

2. The method of claim 1, further comprising:
forming first and second separation grooves adjacent to the first and second partitions.

3. The method of claim 1, wherein the first and second partitions have widths Pw and the first and second separation grooves have widths Pd, and Pw/Pd ranges from about 0.7 to about 1.3.

4. The method of claim 2, wherein the first and second partitions include a plurality of partitions and the first and second separation grooves include a plurality of separation grooves, the plurality of partitions are separated by the plurality of first and second separation grooves, and pinning of the ink droplets occurs in a boundary between the top side and the outer side of the partition that is located at a outermost side.

5. The method of claim 2, further comprising:
forming an ink phobic material layer on at least the top and outer sides of the first and second partitions before the discharging the ink.

6. The method of claim 2, wherein the forming the first and second partitions and the forming the first and second separation grooves includes etching the substrate.

7. The method of claim 2, wherein the forming the first and second partitions and the forming the first and second separation grooves includes forming a photosensitive resin layer on the substrate and etching the photosensitive resin layer.

8. A method for forming a conductive pattern comprising:
forming a first and second partition on a substrate, the first and second partitions including,
inner sides which are spaced apart from each other to define a trench in the substrate,
a top side extending in a lateral direction from top edges of the inner sides of the partition, and
outer sides extending in a downward direction from outer end portions of the top side;
discharging ink into the trench to form ink droplets pinned in a boundary region, the boundary region including a region between the top sides and the outer sides, the ink including conductive particles; and
performing drying and sintering processes to form the conductive pattern in the trench, the conductive pattern including the conductive particles.

9. The method of claim 8, further comprising:
forming separation grooves adjacent to the first and second partitions, the separation grooves having a concave shape.

10. The method of claim 9, wherein the first and second partitions have widths Pw and the separation grooves have widths Pd, and Pw/Pd ranges from about 0.7 to about 1.3.

11. The method of claim 10, further comprising:
forming an ink phobic material layer on at least the top and outer sides of the first and second partitions before the discharging the ink.

12. The method of claim 10, wherein the forming the first and second partitions and the forming the separation grooves includes etching the substrate.

13. The method of claim 10, wherein the forming the first and second partitions and the forming the separation grooves includes forming a photosensitive resin layer on the substrate and etching the photosensitive resin layer.

14. A method of forming a conductive pattern, the method comprising:
forming at least one trench in a substrate;
forming at least first and second grooves on opposite sides of the at least one trench, the at least first and second grooves extending in a substantially same direction as the at least one trench;
discharging ink into the at least one trench, the ink including conductive particles; and
evaporating the ink to form the conductive pattern in the at least one trench.

15. The method of claim 14, wherein the discharging the ink includes discharging the ink into the at least one trench and on a region of the substrate between the first and second grooves.

16. The method of claim 15, wherein the discharging the ink includes discharging at least one ink droplet having an obtuse contact angle with respect to a top surface the region of the substrate between the first and second grooves.

17. The method of claim 14, wherein the forming the at least first and second grooves includes forming the at least first and second grooves to have a depth different from the at least one trench.

18. The method of claim 17, wherein the forming the at least first and second grooves includes forming third and fourth grooves, the third and fourth grooves being formed on opposite sides of the at least one trench and at a distance further from the at least one trench than the first and second grooves.

19. The method of claim 18, wherein the discharging the ink includes discharging the ink such that the ink covers the first and second grooves and a region of the substrate between the third and fourth grooves.

20. The method of claim 19, wherein the discharging the ink includes discharging at least one ink droplet having an obtuse contact angle with respect to a top surface the region of the substrate between the third and fourth grooves.
